(19) United States
(12) Patent Application Publication
(10) Pub. No.: US 2012/0250715 A1
(43) Pub. Date: Oct. 4, 2012

(54) Optoelectronic Semiconductor Component

(75) Inventors: Martin Müller, Bernhardswald (DE); Uwe Strauss, Bad Abbach (DE)

(73) Assignee: OSRAM Opto Semiconductors GmbH, Regensburg (DE)

(21) Appl. No.: 13/257,515

(22) PCT Filed: Jan. 20, 2010
(86) PCT No.: PCT/EP10/50647

§ 371 Date: Mar. 20, 2012

(30) Foreign Application Priority Data
Mar. 19, 2009 (DE) 10 2009 013 909.5

(51) Int. Cl. H01S 5/20

(52) U.S. Cl. 372/45.01

(57) ABSTRACT

In at least one embodiment of the optoelectronic semiconductor component (1), the latter comprises an epitaxially grown semiconductor body (2) with at least one active layer (3). Furthermore, the semiconductor body (2) of the semiconductor component (1) comprises at least one barrier layer (4), the barrier layer (4) directly adjoining the active layer (3). A material composition and/or a layer thickness of the active layer (3) and/or of the barrier layer (4) is varied in a direction of variation or a longitudinal direction (L), perpendicular to a direction of growth (G) of the semiconductor body (2). By varying the material composition and/or the layer thickness of the active layer (3) and/or of the barrier layer (4), an emission wavelength (λ) of a radiation (R) generated in the active layer (3) is likewise adjusted in the direction of variation or in the longitudinal direction (L).

An optoelectronic semiconductor component is provided.

Document DE 100 32 246 A1 relates to a luminescent diode chip based on InGaN and to a method for the production thereof.

An object to be achieved is to provide an optoelectronic semiconductor component which emits electromagnetic radiation at at least two different emission wavelengths.

According to at least one embodiment of the optoelectronic semiconductor component, the latter comprises an epitaxially grown semiconductor body with at least one active layer. It is possible for the entire semiconductor body to be produced solely epitaxially. For example, the semiconductor body comprises precisely one active layer. In addition to the at least one active layer, the semiconductor body may comprise further layers such as cladding layers, waveguide layers, contact layers and/or current spreading layers. For example, the semiconductor body is based on one of the following material systems: GaN, GaP, InGaP, InGaAl, InGaAlP, GaAs or InGaAs.

The active layer preferably includes a pn-junction, a double heterostructure, a single quantum well, SQW for short, or, particularly preferably, a multi quantum well structure, MQW for short, for radiation generation. The active layer particularly preferably includes a single quantum well structure, SQW for short. The term quantum well structure does not here have any meaning with regard to the dimensionality of the quantisation. It thus encompasses inter alia quantum troughs, quantum wires and quantum dots and any combination of these structures.

When the semiconductor component is in operation, electromagnetic radiation is generated in the active layer. The radiation generated in the active layer is preferably in a wavelength range of between 300 nm and 3000 nm inclusive, in particular between 360 nm and 1100 nm inclusive.

According to at least one embodiment of the optoelectronic semiconductor component, the semiconductor body is mounted on a carrier. The carrier may be a growth substrate, on which the semiconductor body is grown. It is also possible for the semiconductor body to be grown on a growth substrate and then rebonded onto a different carrier from the growth substrate.

According to at least one embodiment of the optoelectronic semiconductor component, the semiconductor body comprises at least one barrier layer. The barrier layer is in particular a layer which is in direct contact with the at least one active layer. In other words, the at least one active layer and the at least one barrier layer adjoin one another.

According to at least one embodiment of the optoelectronic semiconductor component, the semiconductor body comprises a direction of variation which, within the bounds of manufacturing tolerances, is oriented perpendicular to a direction of growth of the semiconductor body. The direction of variation may in other words be any desired direction which is oriented perpendicular to the direction of growth.

According to at least one embodiment of the optoelectronic semiconductor component, a material composition and/or a layer thickness of the active layer and/or of the barrier layer is varied. In other words, the material composition and/or the layer thickness of the active layer and/or of the barrier layer varies in particular in the direction of variation. The material composition and/or the layer thickness is/are in this case purposefully adjusted.

According to at least one embodiment of the optoelectronic semiconductor component, an emission wavelength of a radiation generated in the active layer is adjusted in the direction of variation. The emission wavelength is here in particular dependent on the material composition and/or the layer thickness of the at least one active layer and/or the at least one barrier layer. The emission wavelength is thus adjusted by way of the material composition and/or the layer thickness of the active layer and/or the barrier layer in the direction of variation.

In at least one embodiment of the optoelectronic semiconductor chip, the latter includes an epitaxially grown semiconductor body with at least one active layer. Furthermore, the semiconductor body of the semiconductor component comprises at least one barrier layer, the barrier layer directly adjoining the active layer. A material composition and/or a layer thickness of the active layer and/or of the barrier layer is varied in a direction of variation, perpendicular to a direction of growth of the semiconductor body. By varying the material composition and/or the layer thickness of the active layer and/or of the barrier layer, an emission wavelength of a radiation generated in the active layer is likewise adjusted in the direction of variation.

With such a semiconductor component it is possible for radiation of in each case different emission wavelengths to be generated within a single, monolithic semiconductor body at different points of the active layer, wherein the emission wavelength may be adjusted purposefully by way of the characteristics of the active layer and/or of the barrier layer, i.e. by way of the thickness and material composition thereof.

It is for example possible for such an optoelectronic semiconductor component to be used to pump a laser medium. Depending on a pump radiation wavelength, a laser medium exhibits different depths of penetration in terms of the pump radiation into the laser medium. If different pump wavelengths are used, the laser medium may be more uniformly pumped. This more uniform pumping leads for example to improved mode quality or efficiency of laser radiation generated by way of the laser medium.

In order to pump a laser medium with different wavelengths, a plurality of different semiconductor components may be used at the same time, each one or a plurality of the semiconductor components emitting radiation in each case at different emission wavelengths. However, the use of a plurality of mutually different semiconductor components increases the adjustment effort for the semiconductor components. The semiconductor components may also become more readily unadjusted and lead to impairment for instance of the mode quality of the laser radiation generated in the laser medium.

Semiconductor components may likewise be used for pumping in which a plurality of active layers succeed one another in the direction of growth of the semiconductor body. Each of the active layers succeeding one another in the direction of growth then emits for example at a different emission wavelength. However, such a component comprises a comparatively high electrical resistance, which is associated with comparatively high electrical losses in the semiconductor body. Such components are therefore often suitable only to a limited degree for generating relatively high radiation intensities, such as for pumping a laser medium.

A further option for producing a component which generates different emission wavelengths consists in providing different active layers in a direction perpendicular to the direction of growth of the semiconductor body. These active layers situated laterally next to one another may in particular be grown one after the other in different method steps. Such sequential growth of active layers arranged next to one another is complex, since additional, different epitaxial growth steps are needed. This may reduce the yield when producing such a semiconductor component or indeed result in reduced quality and thereby a reduced service life.

According to at least one embodiment of the optoelectronic semiconductor component, the latter has one direction of emission. Within the bounds of manufacturing tolerances the emission direction is oriented preferably both transversely of, in particular perpendicularly to, the direction of growth and transversely of, in particular perpendicularly to, one of the directions of variation. The direction of emission is moreover oriented preferably transversely of, in particular perpendicularly to, the direction of growth. The direction of emission is here in particular that direction in which a maximum radiant intensity is emitted, or that direction which represents a beam axis of the generated, emitted radiation. This does not rule out the possibility of emission of the radiation proceeding in two mutually opposed directions.

In other words, the direction of emission, the direction of growth and this direction of variation are in particular in each case oriented, within the bounds of manufacturing tolerances, in pairs orthogonally to one another. This direction of variation, which is oriented perpendicularly both to the direction of growth and to the direction of emission, is designated hereinafter as the longitudinal direction. The longitudinal direction is thus a specific direction of variation.

According to at least one embodiment of the optoelectronic semiconductor component, the latter takes the form of an edge-emitting semiconductor laser. The radiation generated in the semiconductor component may thus be coherent laser radiation. The direction of emission is then oriented in particular parallel to a resonator axis of a laser resonator, i.e. preferably perpendicular both to the longitudinal direction and to the direction of growth. The direction of emission is for example then arranged perpendicular to resonator mirrors of the laser resonator. It is not necessary for a length of the laser resonator to be smaller than the extent of the semiconductor body in the longitudinal direction.

According to at least one embodiment of the optoelectronic semiconductor component, the latter takes the form of a surface-emitting semiconductor laser. The semiconductor laser then preferably comprises a vertical resonator, in particular the semiconductor laser is thus a “vertical cavity surface emitting laser”, VCSEL for short. It is possible for the semiconductor body then to comprise resonator mirrors in the form for instance of Bragg mirrors. One of the resonator mirrors may also be present as an external component.

If the semiconductor component takes the form of a surface-emitting laser, preferably the resonator axis and therefore in particular also the direction of emission are thus oriented parallel to the direction of growth. The semiconductor component then furthermore preferably displays a transverse direction which is oriented perpendicularly both to the longitudinal direction and to the direction of growth.

According to at least one embodiment of the optoelectronic semiconductor component, the material composition and/or the layer thickness of the active layer and/or of the barrier layer varies, within the bounds of manufacturing tolerances, solely in the longitudinal direction or one of the directions of variation. If the semiconductor component is for example an edge-emitting semiconductor laser, the material composition and the layer thickness are thus constant along the resonator axis of the laser resonator, parallel to the direction of emission, within the bounds of manufacturing tolerances.

According to at least one embodiment of the optoelectronic semiconductor component, a geometric length of the resonator, in particular in a direction perpendicular to a radiation exit side of the semiconductor component and/or parallel to the direction of emission and/or perpendicular to the direction of growth, is constant over the entire semiconductor component and/or over an entire radiation-generating zone of the semiconductor component in particular within the bounds of manufacturing tolerances. In other words, variation of the wavelength emitted is then not achieved by a purposeful, local variation of the resonator length.

According to at least one embodiment of the optoelectronic semiconductor component, the barrier layer is situated between two active layers. The barrier layer here preferably directly adjoins the two active layers. Furthermore, the material composition and/or the layer thickness of the barrier layer is preferably varied in the longitudinal direction or the direction of variation, in particular solely in the longitudinal direction.

According to at least one embodiment of the optoelectronic semiconductor component, the emission wavelength varies by at least 5 nm in the longitudinal direction or in the direction of variation at a radiation passage face of the semiconductor body. The emission wavelength preferably varies in the longitudinal direction or in the direction of variation by at least 7 nm, particularly preferably by at least 10 nm, in particular by at least 15 nm.

According to at least one embodiment of the optoelectronic semiconductor component, a spectral width of the radiation generated in the at least one active layer amounts to at least 5 nm, preferably at least 7 nm, particularly preferably at least 10 nm, in particular at least 15 nm. In other words the semiconductor component then emits in a substantially continuous spectral range with one of the stated spectral widths. The spectral width is here in particular the full width at half maximum, FWHM for short. It is possible for the spectrum of the radiation generated to comprise local minima or maxima within the FWHM width.

According to at least one embodiment of the optoelectronic semiconductor component, the emission wavelength varies monotonically in the longitudinal direction or in the direction of variation within the bounds of manufacturing tolerances. If the longitudinal direction for example defines an x axis, this means, for instance in the event of the emission wavelength increasingly monotonically, that at a position x₁ the wavelength is less than or equal to a wavelength at a position x₂, wherein x₁ is less than x₂. The reverse accordingly applies if the emission wavelength falls monotonically.

According to at least one embodiment of the optoelectronic semiconductor component, the emission wavelength varies periodically in the longitudinal direction or in the direction of variation. The emission wavelength may for example exhibit a sawtooth, square or sinusoidal profile.

According to at least one embodiment of the optoelectronic semiconductor component, the emission wavelength varies in the longitudinal direction or in the direction of variation in the manner of a step function. In other words, the emission wavelength is approximately constant in portions in the longitudinal direction or in the direction of variation and varies in steps between individual portions. The step function preferably falls monotonically or rises monotonically in the longitudinal direction or in the direction of variation.

According to at least one embodiment of the optoelectronic semiconductor component, the emission wavelength varies in linear manner in the longitudinal direction or in the direction of variation, within the bounds of manufacturing tolerances. The emission wavelength may thus be described approximately by a linear equation as a function of an x-position.

According to at least one embodiment of the optoelectronic semiconductor component, the semiconductor body takes the form of a one-piece laser bar. For example, the semiconductor body is a cuboid, monolithic block.

According to at least one embodiment of the optoelectronic semiconductor component, the at least one active layer is continuous in the longitudinal direction or in the direction of variation. The active layer is thus not interrupted, by for example etched trenches, in the longitudinal direction or in the direction of variation.

According to at least one embodiment of the optoelectronic semiconductor component, the latter comprises a plurality of electrical contact zones in the longitudinal direction or in the direction of variation. The contact zones are here designed for electrical contacting of the semiconductor body. For example, a plurality of individual punctiform or stripe-form metal coatings are applied along a top and/or a bottom of the semiconductor body, said top and bottom bounding the semiconductor body in a direction parallel to the direction of growth. In the case of stripe-form contact zones the stripes preferably extend in the direction of emission.

According to at least one embodiment of the optoelectronic semiconductor component, a specific emission wavelength is assigned to each of the contact zones. In other words, within a contact zone the emission wavelength is approximately constant. It is then possible for individual contact zones, in particular groups of contact zones exhibiting a specific emission wavelength, to be separately electrically drivable. In this way the intensity of specific emission wavelengths may be purposefully adjusted in relation to the intensity of other emission wavelengths.

According to at least one embodiment of the optoelectronic semiconductor component, the latter comprises between 10 and 100 contact zones inclusive, which are arranged in the longitudinal direction or in the direction of variation of the semiconductor body.

According to at least one embodiment of the optoelectronic semiconductor component, a lengthwise extent of the semiconductor component in the longitudinal direction or in the direction of variation is between 3 mm and 20 mm inclusive, in particular between 5 mm and 15 mm inclusive. The extent of the semiconductor body in the direction of emission, in particular a resonator length, lies in the range between 0.5 mm and 10 mm inclusive, in particular between 1.5 mm and 4 mm inclusive.

According to at least one embodiment of the optoelectronic semiconductor component, the latter is designed to generate an average radiant power of at least 30 W, in particular of at least 100 W. The semiconductor component may here be operated in Continuous Wave mode, or CW mode for short, or in a pulsed mode.

According to at least one embodiment of the optoelectronic semiconductor chip, the layer thickness of the active layer and/or of the barrier layer in the longitudinal direction or in the direction of variation varies between 0.3 nm and 3.0 nm inclusive, in particular between 0.4 nm and 1.5 nm inclusive.

According to at least one embodiment of the optoelectronic semiconductor chip, the active layer comprises indium. The emission wavelength may then be adjusted in particular by way of an indium content, for example.

According to at least one embodiment of the optoelectronic semiconductor component, in which the active layer comprises indium, the indium content of the active layer varies in the longitudinal direction or in the direction of variation by between 0.5 percentage points and 10 percentage points inclusive, in particular by between 3 percentage points and 7 percentage points inclusive. The indium content here relates to the proportion of gallium lattice sites which are occupied by indium instead of gallium, for instance in the case of an AlGaAs-based semiconductor body.

According to at least one embodiment of the optoelectronic semiconductor component, the indium content of the active layer amounts to between 1% and 30% inclusive, in particular between 3% and 27% inclusive. However, it is for example also possible for the indium content to amount to between 18% and 27% inclusive.

According to at least one embodiment of the optoelectronic semiconductor component, the latter comprises at least two, preferably at least three active layers, which succeed one another in the direction of growth. In the case of at least one, preferably in the case of all the active layers, the material composition and/or the layer thickness of the active layers themselves or of the at least one barrier layer varies in one of the directions of variation, in particular solely in the longitudinal direction. Particularly preferably, neighbouring active layers in the direction of growth have different emission wavelengths in a direction parallel to the direction of growth.

According to at least one embodiment of the optoelectronic semiconductor component, the latter is an edge-emitting laser and the semiconductor body is based on the AlGaAs material system. The indium content of the at least one active layer is varied in the longitudinal direction by at least 0.8 percentage points. Furthermore, the emission wavelength varies in the longitudinal direction by at least 7 nm. In addition, the variation in emission wavelength in the longitudinal direction may be described by a linear function.

A device for pumping a laser medium is additionally provided. The device may for example include at least one optoelectronic semiconductor component as described in relation to at least one of the above-stated embodiments.

According to at least one embodiment of the device, the latter comprises at least one laser medium, the laser medium being optically pumped by the semiconductor component. The laser medium is preferably a solid-state laser medium. The laser medium is for example a doped garnet or a doped glass.

According to at least one embodiment of the device, the latter comprises at least two, in particular at least three optoelectronic semiconductor components, as indicated in conjunction with one of the above-described embodiments.

In addition to use for pumping laser media, optoelectronic semiconductor components described herein may also be used in display means or in lighting devices for projection purposes. Use in floodlights or spotlights or in general lighting is also possible, as well as in materials processing.

An optoelectronic semiconductor component described herein and a device described herein for pumping a laser medium will be explained in greater detail below with reference to the drawings and with the aid of exemplary embodiments. Elements which are the same in the individual figures are indicated with the same reference numerals. The relationships between the elements are not shown to scale, however, but rather individual elements may be shown exaggeratedly large to assist in understanding.

In the drawings:

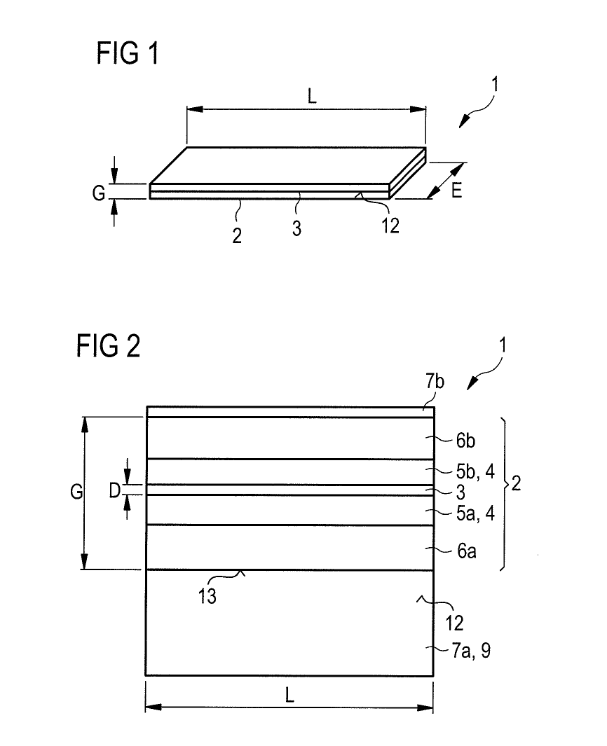

FIG. 1 is a schematic three-dimensional representation of an optoelectronic semiconductor component described herein,

FIGS. 2 to 4 show schematic side views of further exemplary embodiments of optoelectronic semiconductor components described herein,

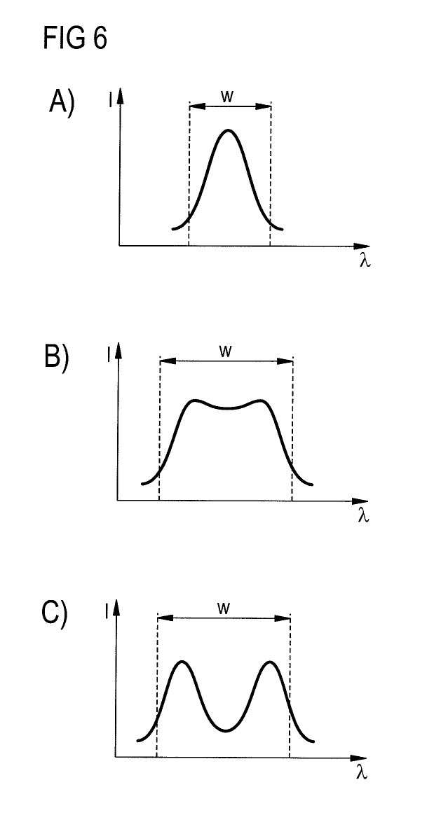

FIGS. 5 and 6 show schematic illustrations of spectral properties of optoelectronic semiconductor components described herein,

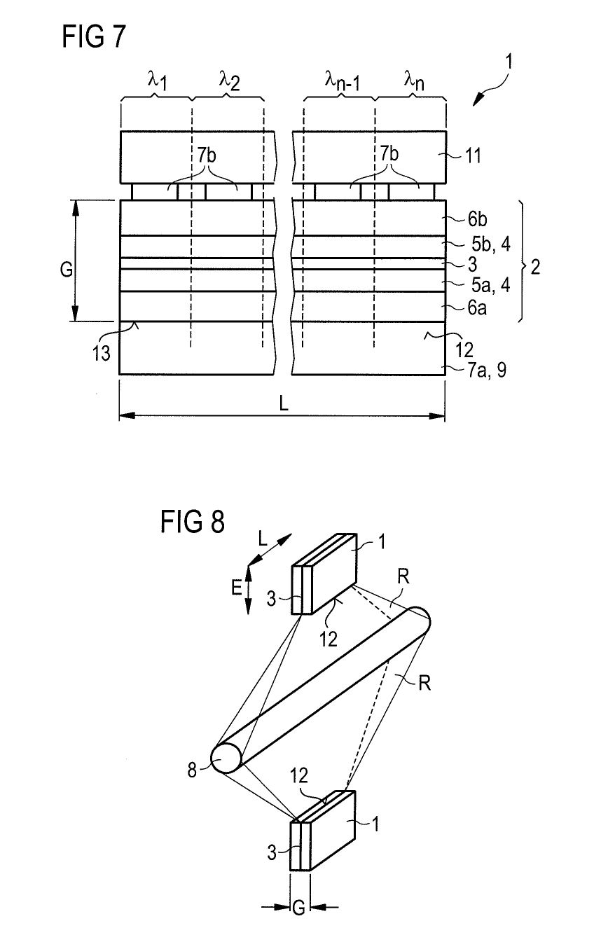

FIG. 7 is a schematic side view of a further exemplary embodiment of an optoelectronic semiconductor component described herein,

FIG. 8 shows a schematic three-dimensional representation of an exemplary embodiment of a device described herein for pumping a laser medium, and

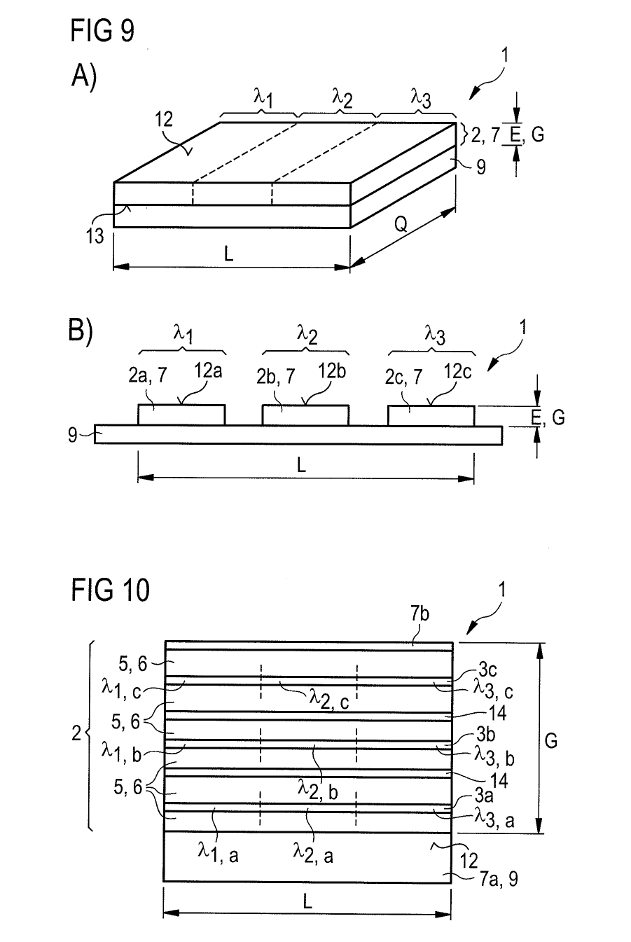

FIGS. 9 and 10 show schematic representations of further exemplary embodiments of optoelectronic semiconductor components described herein.

FIG. 1 shows a schematic three-dimensional representation of an exemplary embodiment of an optoelectronic semiconductor component 1. A semiconductor body 2 comprises an active layer 3. Electromagnetic radiation is generated in the active layer 3 when the semiconductor component 1 is in operation.

The semiconductor component 1 preferably takes the form of an edge-emitting laser or indeed a super luminescent diode. The generation of radiation in the active layer 3 is thus based in particular on stimulated emission. For example, the radiation generated in the active layer 3 leaves the semiconductor body 2 at a radiation passage face 12 with a main direction of emission perpendicular to the radiation passage face 12.

If the semiconductor component 1 takes the form of a laser, the radiation passage face 12 and a side of the semiconductor body 2 opposite the radiation passage face 12, in each case at least in part, form resonator end faces. A geometric resonator length, and thus in particular also an extent of the semiconductor body 2 in the direction of emission E, amounts for example to between 1 mm and 5 mm inclusive.

The active layer 3 is of planar construction within the bounds of manufacturing tolerances. The semiconductor body 2 is produced by epitaxial growth. Within the bounds of manufacturing tolerances a direction of growth G is oriented perpendicular to the direction of emission E and thus forms a normal to the active layer 3. An extent of the semiconductor body 2 in the direction of growth G preferably amounts to less than 500 μm, in particular to less than 200 μm. Non-semiconducting materials such as heat sinks or metallic contacts do not here belong to the semiconductor body 2 and are not shown in FIG. 1.

A longitudinal direction L of the semiconductor body 2 is oriented perpendicular to the direction of growth G and perpendicular to the direction of emission E. The extent of the semiconductor body 2 in the longitudinal direction L amounts to for example between 5 mm and 15 mm. A material composition and/or a layer thickness of the active layer or of barrier layers 4 adjoining the active layer is varied in the longitudinal direction L. By way of this variation in the layer thickness and/or the material composition, an emission wavelength λ of the radiation is adjusted as a function of the position of the semiconductor body 2 in the longitudinal direction L.

FIG. 2 shows a schematic side view of the radiation passage face 12 of the semiconductor component 1. The semiconductor body 2 is formed on for example a GaAs substrate, which forms a carrier 9. An electrical contact zone 7a is formed by the carrier 9, for example on an n-conducting side of the semiconductor body 2. An n-cladding layer 6a has been grown on the top 13 of the carrier 9.

An n-waveguide layer 5a is situated on a side of the cladding layer 6a remote from the carrier 9. In the direction away from the carrier 9 the waveguide layer 5a is followed by the active layer 3, a p-waveguide layer 5b, a p-cladding layer 6b and an electrical contact zone 7b. The contact zone 7b may be formed by one or more metal coatings. The epitaxially grown semiconductor body 2 is thus formed by the cladding layers 6a, 6b, the waveguide layers 5a, 5b and the active layer 3. The semiconductor body 2 may optionally also include at least one epitaxially grown contact layer, not shown in FIG. 2, which is situated between the cladding layer 6b and the contact layer 7b.

The two waveguide layers 5a, 5b are in direct contact with the active layer 3. The waveguide layers 5a, 5b thus at the same time constitute the barrier layers 4.

The thicknesses of the waveguide layers 5a, 5b, the cladding layers 6a, 6b and the active layer 3 are constant over the entire longitudinal direction L within the bounds of manufacturing tolerances. The thickness of the cladding layers 6a, 6b amounts in each case to around 1 μm. The waveguide layers 5a, 5b each exhibit a thickness, in the direction of growth G, of around 500 nm. The thickness D of the active layer 3 is around 8 nm.

The material composition of the active layer 3 is varied in the longitudinal direction L. If the semiconductor body is based for example on the AlGaAs material system, an indium content in particular of the active layer 3 is varied by around 3 percentage points to 7 percentage points, such that the emission wavelength λ of the radiation is varied in the longitudinal direction L by around 30 nm. The absolute indium content of the active layer 3 is here for example between 20% and 30% inclusive. Perpendicular to the radiation passage face 12, i.e. parallel to the direction of emission E, the material composition as well as the thickness D of the active layer 3 are constant within the bounds of manufacturing tolerances.

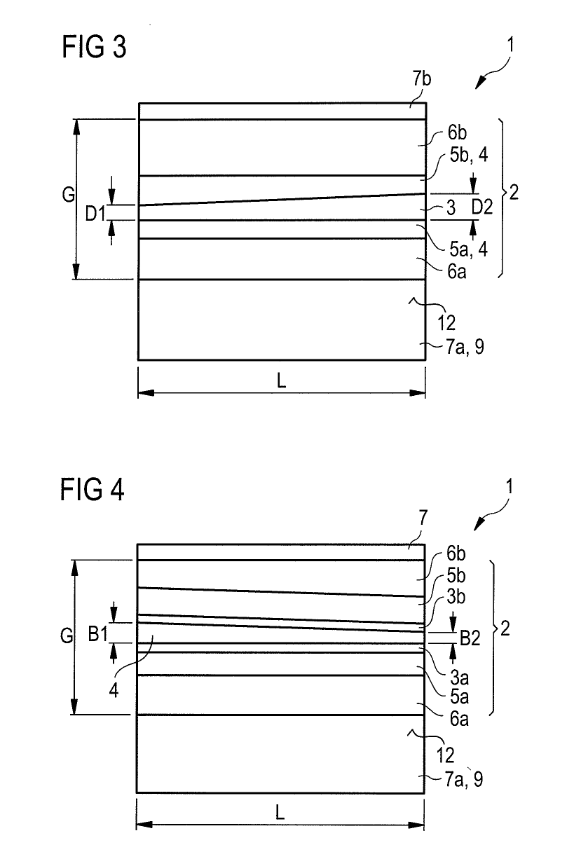

In the exemplary embodiment of the semiconductor component 1 according to FIG. 3 the thickness of the active layer 3 is varied. The thickness in the direction parallel to the direction of growth G corresponds on one side of the semiconductor body 2 to a value D1. The thickness grows in linear manner in the longitudinal direction L within the bounds of manufacturing tolerances to a value D2. Perpendicular to the radiation passage face 12 the thickness remains constant in each case, within the bounds of manufacturing tolerances. The thickness D1 amounts to around 7.0 nm for example, and the thickness D2 to around 8.5 nm. The wavelength increases for example from around 800 nm to around 810 nm over the thickness profile from D1 to D2.

In addition to the variation of the thickness D1, D2 of the active layer 3, it is optionally likewise possible additionally to vary the material composition of the active layer 3 in the longitudinal direction L. Alternatively or in addition, the material composition of the barrier layers 4, here formed by the waveguide layers 5a, 5b, may also be varied.

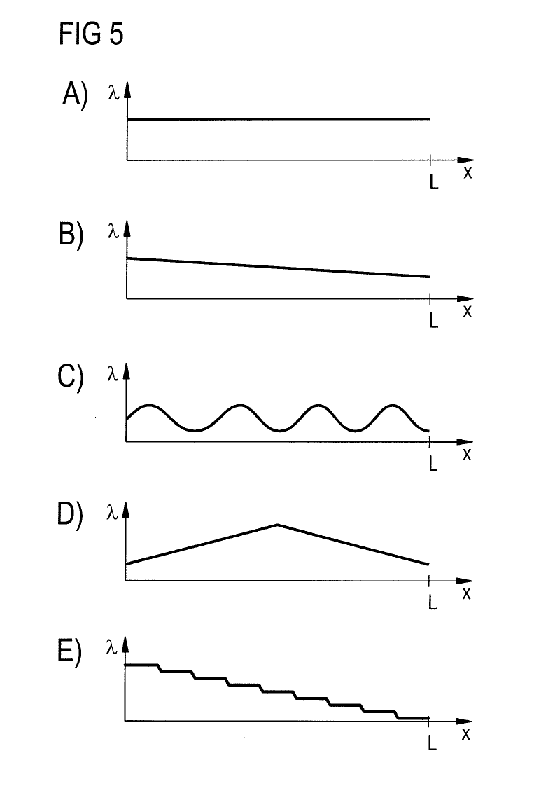

In the exemplary embodiment of the semiconductor component 1 according to FIG. 4, the semiconductor body 2 comprises two active layers 3a, 3b. Between these active layers 3a, 3b there is located a barrier layer 4 different from the waveguide layers 5a, 5b. In the longitudinal direction L the thickness of the barrier layer 4 decreases from a value B1 to a value B2. For example, the value B1 amounts to around 10 nm and the value B2 to around 8 nm.

Coupling of the two active layers 3a, 3b to one another takes place across the barrier layer 4. This coupling has an influence for example on the energy level structure of quantum wells of the active layers 3a, 3b. For example, the emission wavelength of the radiation generated in the active layers 3a, 3b is shifted increasingly into the longer wave spectral range as the thickness of the barrier layer 4 decreases.

The options explained in relation to FIGS. 2 to 4 for adjusting the emission wavelength λ of the radiation may in particular also be combined together in a single component. Thus, for example, the material composition of the at least one active layer 3 and the thickness of the barrier layer 4 may be varied and adjusted in combination.

In FIG. 5 profiles of the emission wavelength λ are shown plotted against a position in the longitudinal direction L. According to FIG. 5A a wavelength is constant and thus not varied in the longitudinal direction L. A corresponding semiconductor component emits radiation only in a comparatively narrow spectral range.

FIGS. 5B to 5E show profiles of the emission wavelength λ for semiconductor components 1 for instance according to FIGS. 1 to 4. According to FIG. 5B the emission wavelength λ decreases in linear manner in the longitudinal direction L.

FIG. 5C shows a sinusoidal profile of the emission wavelength λ in the longitudinal direction L. According to FIG. 5D the emission wavelength λ increases initially in linear manner relative to the longitudinal direction L as the position increases, and then decreases again in linear manner.

The profile of the emission wavelength λ according to FIG. 5E takes the form of a step function, i.e. the emission wavelength λ is approximately constant within given regions and varies in steps between individual plateaus.

Other profiles are also possible in addition to the profiles shown in FIGS. 5B to 5E. The emission wavelength λ may for example vary in a sawtooth-like manner in the longitudinal direction L or be a combination of the profiles shown.

In FIG. 6 an intensity I of the radiation emitted by the semiconductor component 1 is plotted against the emission wavelength λ. According to FIG. 6A the radiation has a comparatively small spectral width w. The spectrum illustrated corresponds approximately to that of a semiconductor element according to FIG. 5A, in which the wavelength is not adjusted or varied in the longitudinal direction.

The intensity distribution according to FIG. 6B stems for example from a semiconductor component 1 described herein according to FIG. 5B, in which the emission wavelength λ is varied in linear manner in the longitudinal direction L. The intensity distribution exhibits a comparatively large spectral width w. The spectrum exhibits a wide maximum, over which the intensity I is approximately constant over a relatively large spectral range. The spectral width w according to FIG. 6B is for example at least three times the spectral width w according to FIG. 6A of a semiconductor element in which the emission wavelength λ is not adjusted and varied.

According to FIG. 6C the intensity I, plotted against the emission wavelength λ, has two maxima separated from one another by a pronounced minimum. Such a spectrum may result from a semiconductor component 1 for example according to FIG. 5E, in which the emission wavelength λ displays a profile in the form of a step function in the longitudinal direction L. Unlike that shown in FIG. 6C, the spectrum may also exhibit markedly more than two maxima. According to FIG. 6C too, the spectral width w is markedly greater than for instance according to FIG. 6A.

In the case of the semiconductor component 1 according to FIG. 7, a plurality of electrical contact zones 7b are applied to a side of the semiconductor body 2 remote from the carrier 9. The contact zones 7b take the form of stripes for example, the contact zones 7b extending primarily in a direction perpendicular to the radiation passage face 12, parallel to the direction of emission E. The semiconductor body 2 in this case preferably exhibits a low electrical transverse conductivity in a direction parallel to the longitudinal direction L, such that energisation of the active layer 3 proceeds approximately only parallel to the direction of growth G, starting from the contact zones 7b.

The electrical contact zones 7b cover for example a proportion of the area of the side of the semiconductor body 2 remote from the carrier 9 of between 10% and 95% inclusive, in particular between 50% and 80% inclusive. The width of the contact zones 7b in the longitudinal direction is preferably between 10 μm and 300 μm inclusive, in particular between 50 μm and 200 μm inclusive.

Alternatively or in addition, it is also possible for the electrical contact zones 7a on the carrier 9 likewise to take the form of stripes for example, like the contact zones 7b.

It is in particular possible for the semiconductor component 1 to comprise between 5 and 100 such contact zones 7b inclusive. A wavelength λ₁ to λₙ generated in the active layer 3 may for example be assigned to each of the contact zones 7b. The contact zones 7b may likewise be individually electrically drivable. In this way, purposeful adjustment of the intensity I of the radiation may be effected as a function of the emission wavelength λ.

On a side of the contact zones 7b and/or of the carrier 9 remote from the carrier 9 at least one heat sink 11 may optionally be mounted. Heat arising during operation of the semiconductor component 1 may be dissipated efficiently in particular out of the semiconductor body 2 by way of the at least one heat sink 11. The carrier 9 and/or the heat sink 11 may be a metal, sapphire, GaN, SiC, GaSb or InP. It is also possible for the carrier 9 and the heat sink 11 to be composite bodies.

FIG. 8 shows an exemplary embodiment of a device for pumping a laser medium 8. Two optoelectronic semiconductor components 1, for instance according to FIGS. 1 to 7, serve for optical pumping of the laser medium 8. The radiation R, which leaves the radiation passage faces 12 in the region of the active layer 3, is guided directly to the laser medium 8. The emission wavelength λ is varied along the active layers 3 parallel to the longitudinal direction L. In the laser medium 8 absorption of the pump radiation R takes place which is relatively uniform over the volume of the laser medium 8.

Optionally, optical elements which are not shown, such as light guides, lenses or mirrors, may be mounted between the optoelectronic semiconductor components 1 and the laser medium 8, in order for example to bring about uniform mixing of the radiation R generated by the semiconductor components 1 and in order to ensure spectrally uniform illumination of the laser medium 8.

FIG. 9A shows a three-dimensional schematic representation of a further exemplary embodiment, according to which the semiconductor component 1 takes the form of a surface-emitting laser, VCSEL for short. The direction of emission E is here oriented parallel to the direction of growth G. The radiation passage face 12 is likewise oriented perpendicular to the direction of growth G. A transverse direction Q is oriented both perpendicular to the direction of growth G and perpendicular to the longitudinal direction L.

The semiconductor body 2 comprises three continuous zones, in which radiation of different emission wavelengths λ₁, λ₂, λ₃ is emitted. The material composition and/or the layer thickness of the at least one active layer of the semiconductor body 2 is preferably varied solely in the longitudinal direction L, while in the transverse direction Q the material composition and/or the layer thickness is thus preferably constant. The material composition and/or the layer thickness is for example varied in the longitudinal direction L in the manner of a step function, as in FIG. 5E.

In the exemplary embodiment of the semiconductor component 1 according to the side view in FIG. 9B, the semiconductor bodies 2a, 2b, 2c are grown on the common carrier 9. In operation radiation of different emission wavelengths λ₁, λ₂, λ₃ is generated in each of the semiconductor bodies 2a, 2b, 2c.

According to the side view in FIG. 10, the semiconductor component 1 in the form of an edge-emitting laser comprises three active layers 3a, 3b, 3c, which follow one another in the direction of growth G. The radiation passage face 12 is oriented parallel to the plane of the drawing. Between neighbouring active layers 3a, 3b, 3c there are in each case situated the cladding layers 6, the waveguide layers 5 and a tunnel diode 14. In each of the active layers 3a, 3b, 3c the layer thickness and/or the material composition is varied in the longitudinal direction L. Variation proceeds for example in the manner of a step function, like in FIG. 5E.

For the emission wavelengths λ_{1,a}, λ_{2,a}, λ_{3,a} of the active layer 3a closest to the carrier 9, the following applies for example: λ_{1,a}<λ_{2,a}<λ_{3,a}. The emission wavelengths λ_{1,a}, λ_{1,c} of the active layers 3a, 3b, 3c, generated in the direction of growth G, are likewise preferably different from one another. The following applies, for example: λ_{1,a}>λ_{1,b}>λ_{1,c}. The same may also apply for the emission wavelengths λ_{2,a}, λ_{2,b}, λ_{2,c}, λ_{3,a}, λ_{3,b}, λ_{3,c}.

In other words it is possible for the radiation passage face to comprise sub-zones arranged in a matrix in plan view. A different emission wavelength may be emitted in each of the sub-zones. The emission wavelength is thus varied for example both in the longitudinal direction L and, by means of the stack-like arrangement of the active layers 3a, 3b, 3c, in the direction of growth G.

The invention described herein is not restricted by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

This patent application claims priority from German patent application 10 2009 013 909.5, whose disclosure content is hereby included by reference.

1. An optoelectronic semiconductor component comprising:
an epitaxially grown semiconductor body with at least one active layer;
at least one barrier layer, which directly adjoins the active layer,
wherein a material composition and/or a layer thickness of the active layer and/or of the barrier layer is varied in a direction of variation, perpendicular to a direction of growth of the semiconductor body, and
wherein by varying the material composition and/or the layer thickness of the active layer and/or the barrier layer, an emission wavelength of a radiation generated in the active layer is adjusted in the direction of variation.

2. The optoelectronic semiconductor component according to claim 1, which is an edge-emitting semiconductor laser or a surface-emitting semiconductor laser.

3. The optoelectronic semiconductor component according to claim 1, wherein the material composition and/or the layer thickness of the active layer and/or of the barrier layer is varied only in a longitudinal direction, perpendicular to a direction of emission and perpendicular to the direction of growth, wherein the direction of emission is oriented transversely of the direction of growth.

4. The optoelectronic semiconductor component according to claim 3, wherein the emission wavelength (λ) varies by at least 5 nm at a radiation passage face in the direction of variation or in the longitudinal direction.

5. The optoelectronic semiconductor component according to claim 3, wherein the emission wavelength (λ) varies monotonically in the direction of variation or in the longitudinal direction.

6. The optoelectronic semiconductor component according to claim 3, wherein the emission wavelength (λ) varies periodically and/or in the form of a step function in the direction of variation or in the longitudinal direction.

7. The optoelectronic semiconductor component according to claim 1, wherein the semiconductor body takes the form of a one-piece laser bar.

8. The optoelectronic semiconductor component according to claim 3, wherein the at least one active layer is continuous in the direction of variation or in the longitudinal direction.

9. The optoelectronic semiconductor component according to claim 3, which comprises a plurality of electrical contact zones in the direction of variation or in the longitudinal direction, which contact zones are designed for electrical contacting of the semiconductor body, and in which a specific emission wavelength (λ) is assigned to each of the contact zones.

10. The optoelectronic semiconductor component according to claim 3, wherein the extent of the semiconductor body is between 3 mm and 30 mm inclusive in the direction of variation or in the longitudinal direction and between 1 mm and 10 mm inclusive in the direction of emission.

11. The optoelectronic semiconductor component according to claim 1, which is designed to generate an average radiant power of at least 30 W.

12. The optoelectronic semiconductor component according to claim 3, wherein the layer thickness of the active layer and/or the barrier layer is varied in the direction of variation or in the longitudinal direction by between 0.3 nm and 3.0 nm inclusive.

13. The optoelectronic semiconductor component according to claim 3, wherein the active layer comprises In, and in which an In content of the active layer is varied in the direction of variation or in the longitudinal direction between 0.5 percentage points and 10 percentage points inclusive.

14. The optoelectronic semiconductor component according to claim 3, wherein the semiconductor body is based on the AlGaAs material system,
wherein the In content of the at least one active layer is varied by at least 0.5 percentage points in the longitudinal direction,
wherein the emission wavelength (λ) varies in the longitudinal direction by at least 5 nm, and
in which wherein the emission wavelength (λ) varies in linear manner in the longitudinal direction.

15. A device for pumping a laser medium, comprising:
at least one optoelectronic semiconductor component according to claim 1; and
at least one laser medium,
wherein the laser medium is optically pumped by the semiconductor component.
